(19) United States
(12) Patent Application Publication
(10) Pub. No.: US 2015/0343596 A1
(43) Pub. Date: Dec. 3, 2015

(54) CIRCULAR POLISHING PAD

(71) Applicant: TOYO TIRE & RUBBER CO., LTD., Osaka-shi, Osaka (JP)

(72) Inventor: Tsuyoshi KIMURA, Osaka (JP)

(21) Appl. No.: 14/654,833

(22) PCT Filed: Dec. 4, 2013
(86) PCT No.: PCT/JP2013/082592

§ 371 Date: Jun. 22, 2015

(30) Foreign Application Priority Data
Dec. 28, 2012 (JP) 2012-288021

(51) Int. Cl. B24B 37/26; B24D 11/00; H01L 21/67; H01L 21/02; H01L 21/306

(52) U.S. Cl. CPC B24B 37/26; H01L 21/0201; H01L 21/30625; H01L 21/67092; B24D 11/003

(57) ABSTRACT

A circular polishing pad includes a circular polishing layer having XY grid grooves on a polishing surface. The center point of the circular polishing layer is offset in a region (Z) (including imaginary straight lines) enclosed by three imaginary straight lines (A, B, and C) each shifted by a groove pitch of 5% in relation to reference lines defined by an X groove or a Y groove. The circular polishing pad can minimize polishing unevenness on the surface of a material to be polished.

### TECHNICAL FIELD

The present invention relates to a polishing pad (for rough polishing or final polishing) used in polishing the surfaces of optical materials such as a lens and a reflecting mirror etc., a silicon wafer, a glass substrate for a hard disc and an aluminum substrate etc.

### BACKGROUND ART

Production of a semiconductor device involves a step of forming an electroconductive film on the surface of a wafer to form a wiring layer by photolithography, etching etc., a step of forming an interlaminar insulating film on the wiring layer, etc., and an uneven surface made of an electroconductive material such as metal and an insulating material is generated on the surface of a wafer by these steps. In recent years, processing for fine wiring and multilayer wiring is advancing for the purpose of higher integration of semiconductor integrated circuits, and accordingly techniques of planarizing an uneven surface of a wafer have become important.

As the method of planarizing an uneven surface of a wafer, a CMP method is generally used. CMP is a technique wherein while the surface of a wafer to be polished is pressed against a polishing surface of a polishing pad, the surface of the wafer is polished with slurry having abrasive grains dispersed therein. As shown in FIG. 1, a polishing apparatus used generally in CMP is provided for example with a polishing platen 2 for supporting a polishing pad 1, a supporting stand (polishing head) 5 for supporting a material to be polished (wafer) 4, a backing material for uniformly pressurizing a wafer, and a mechanism of feeding an abrasive. The polishing pad 1 is fitted with the polishing platen 2 for example via a double-sided tape. The polishing platen 2 and the supporting stand 5 are provided with rotating shafts 6 and 7 respectively and are arranged such that the polishing pad 1 and the material to be polished 4, both of which are supported by them, are opposed to each other. The supporting stand 5 is provided with a pressurizing mechanism for pushing the material to be polished 4 against the polishing pad 1.

Usually, the polishing surface in contact with a material to be polished of a polishing pad has grooves for holding and renewing a slurry. The shape of the grooves of the conventional polishing pad includes radial grooves, concentric grooves, XY grid grooves, spiral grooves, and the like. In the CMP process, the slurry supplied in the center of the polishing pad flows along the groove from the center to the outside by the centrifugal force generated by the rotation of the polishing pad and is finally discharged to the outside of the polishing pad.

In general, grooves on the polishing surface are regularly arranged so as to uniformly supply the slurry onto the polishing surface. For example, in the case of XY grid grooves, such grooves are arranged in such a way that the intersection point of the X groove and the Y groove coincides with the center point of the polishing pad. Further, in the case of spiral grooves, they are arranged so that their starting point coincides with the center point of the polishing pad.

However, when the grooves on the polishing surface are regularly arranged, polishing unevenness (polishing marks) due to the influence of the groove pattern may sometimes occur on the surface of a material to be polished. Conventionally, in order to reduce such polishing unevenness, CMP is carried out while reciprocating the supporting stand (polishing head) 5 in the radial direction of the polishing platen 2. This reciprocating motion is commonly referred to as “rocking” or “oscillation”.

However, when the supporting stand 5 is reciprocated, the material to be polished is easily shifted or damaged. Also, it is necessary to use an expensive CMP apparatus having an oscillation mechanism. In addition, since there are differences in the oscillation mechanism depending on the CMP apparatus to be used, it becomes complicated to adjust the oscillation. Further, in the case of a long-term CMP treatment, it is difficult for oscillation alone to minimize the occurrence of polishing unevenness.

In order to minimize such polishing unevenness, Patent Document 1 has proposed a circular polishing pad provided with a spiral groove pattern on the surface, wherein the center point of the groove pattern is offset from the center point of the circular polishing pad.

Further, Patent Document 2 has proposed a polishing pad wherein the symmetry axis of a groove pattern is offset from the center point of the polishing pad surface.

However, the effect of minimizing polishing unevenness was not sufficient in the conventional polishing pad.

### PRIOR ART DOCUMENTS

### Patent Documents

Patent Document 1: JP-A-2008-290197

Patent Document 2: US 2009/0081932 A

### SUMMARY OF THE INVENTION

### Problems to be Solved by the Invention

The purpose of the present invention is to provide a circular polishing pad with which polishing unevenness on the surface of a material to be polished can be effectively minimized.

### Means for Solving the Problems

As a result of investigations for solving the problems described above, the inventors have found that the objects can be achieved by the polishing pad described below, and have completed the invention.

Thus, the invention is directed to a circular polishing pad including a circular polishing layer having XY grid grooves on a polishing surface, wherein the center point of the circular polishing layer is offset in a region Z (including imaginary straight lines) enclosed by the following three imaginary straight lines A, B and C:

imaginary straight line A: a straight line joining a point on an X groove or a Y groove with a point shifted by a groove pitch of 5% in a direction perpendicular to the X groove or Y groove,

imaginary straight line B: a straight line joining a point on one diagonal line D of an XY grid groove with a point shifted by a groove pitch of 5% in a direction perpendicular to the diagonal line D, and

imaginary straight line C: a straight line joining a point on the other diagonal line E of the XY grid groove with a point shifted by a groove pitch of 5% in a direction perpendicular to the diagonal line E.

As described in the present invention, an opposing state between the surface to be polished and the grooves during polishing can be made non-uniform by offsetting the center point of the circular polishing layer in the region Z (including imaginary straight lines). Consequently, it is possible to effectively minimize the occurrence of polishing unevenness because the grooves does not always face the specific portion of the surface to be polished, thereby causing a uniform polishing of the entire surface to be polished.

If the center point of the circular polishing layer is arranged outside the offset region Z, more specifically, if the center point of the circular polishing layer is arranged so as to coincide with the intersection point of the X and Y grooves, if the center point of the circular polishing layer is arranged on the X groove or Y groove, if the center point of the circular polishing layer is arranged on the diagonal line of the XY grid grooves, or if the degree of offset is less than 5% of the groove pitch, the opposing state between the surface to be polished and the grooves cannot be made non-uniform sufficiently during polishing. As a result, the groove always faces the specific portion of the surface to be polished, so that the surface to be polished is non-uniformly polished to easily cause the occurrence of polishing unevenness. In particular, the central portion of the surface to be polished is excessively polished or insufficiently polished, so that the polishing unevenness tends to occur in the center of the surface to be polished.

Also, the invention relates to a method for producing the circular polishing pad, comprising the steps of:

forming an XY grid groove in a polishing sheet, and

preparing a circular polishing layer by cutting the polishing sheet into a circular shape with reference to the center point that is offset in the region Z.

Also, the invention relates to a method for manufacturing a semiconductor device, comprising the step of polishing the surface of a semiconductor wafer by using the circular polishing pad.

### Effect of the Invention

As described above, the circular polishing pad of the present invention can effectively minimize the polishing unevenness on the surface of a material to be polished because the center point of the circular polishing layer is arranged in the specific offset region.

### BRIEF DESCRIPTION OF THE DRAWINGS

FIG. 1 is a schematic configuration view showing an example of a polishing apparatus used in CMP polishing.

FIG. 2 is a schematic view showing an offset region Z in the present invention.

FIG. 3 is a schematic view showing a preferable range of the offset region Z in the present invention.

FIG. 4 is a photograph showing the state of the polished surface after polishing a wafer using the circular polishing pad of Example 1.

FIG. 5 is a photograph showing the state of the polished surface after polishing a wafer using the circular polishing pad of Comparative Example 1.

### MODE FOR CARRYING OUT THE INVENTION

A material of the circular polishing layer of the present invention is not restricted. For example, the material may be one of or a blend of two or more of polyurethane resin, polyester resin, polyamide resin, acrylic resin, polycarbonate resin, halogen-containing resin (such as polyvinyl chloride, polytetrafluoroethylene and polyvinylidene fluoride etc.), polystyrene, olefin resin (such as polyethylene and polypropylene etc.), epoxy resin, and photosensitive resin. Polyurethane resin is preferred as a material for forming the circular polishing layer because polyurethane resin has good wear resistance and because urethane polymers having desired physical properties can be easily obtained through changing the composition of raw materials in various manners.

The circular polishing layer may be a foamed body or may be a non-foamed body, but is preferably formed of polyurethane resin foam.

Manufacturing methods of the polyurethane resin foam include: a method in which hollow beads are added, a mechanical foaming method, a chemical foaming method and the like.

An average cell diameter of the polyurethane resin foam is preferably in the range of from 30 to 80 μm and more preferably in the range of from 30 to 60 μm. If an average cell diameter falls outside the range, a tendency arises that a polishing rate is decreased and a planarity of a material to be polished (a wafer) after polishing is reduced.

Preferably, the polyurethane resin foam has a specific gravity ranging from 0.5 to 1.3. When the specific gravity is less than 0.5, the surface strength of the circular polishing layer decreases, so that the planarity of a material to be polished tends to decrease. When the specific gravity is larger than 1.3, the cell number on the surface of the circular polishing layer decreases, so that the polishing rate tends to decrease despite excellent planarity.

Preferably, the polyurethane resin foam has a hardness measured by ASKER D hardness meter, ranging from 45 to 70 degrees. When the ASKER D hardness is less than 45 degrees, the planarity of a material to be polished decreases, while when the hardness is more than 70 degrees, the uniformity of a material to be polished tends to decrease despite excellent planarity.

The size of the circular polishing layer is not particularly limited, but is usually about 30 to 100 cm in diameter.

A window for optical end point detection (light transmitting region) may be provided on the circular polishing layer.

The thickness of the circular polishing layer is generally, but is not limited to, about 0.8 to 4 mm, and preferably 1.5 to 2.5 mm. As a method of producing a circular polishing layer having the thickness described above, examples thereof include a method of slicing a foam block to a predetermined thickness by using a band saw-type or plane-type slicer; a method of casting a resin into a mold having a cavity of a predetermined thickness, followed by curing; and a method of using a coating technique or a sheet molding technique.

Hereinafter, a circular polishing pad wherein the center point of the circular polishing layer is offset in the region Z (including imaginary straight lines) will be described in detail.

FIG. 2 is a schematic view showing an offset region Z in the present invention.

As shown in FIG. 2, the offset region Z (8) is a region enclosed by the following three imaginary straight lines A (9), B (10) and C (11), and there are 4 offset regions in one XY grid groove:

imaginary straight line A (9): a straight line joining a point on an X groove 12 or a Y groove 13 with a point shifted by a groove pitch of 5% in a direction perpendicular to the X groove 12 or Y groove 13,

imaginary straight line B (10): a straight line joining a point on one diagonal line D (14) of an XY grid groove with a point shifted by a groove pitch of 5% in a direction perpendicular to the diagonal line D (14), and

imaginary straight line C (11): a straight line joining a point on the other diagonal line E (15) of the XY grid groove with a point shifted by a groove pitch of 5% in a direction perpendicular to the diagonal line E (15).

The imaginary straight line B (10) is a straight line joining a point on one diagonal line D (14) of an XY grid groove with a point shifted by a groove pitch of preferably 10%, more preferably 15%, in a direction perpendicular to the diagonal line (14).

The imaginary straight line C (11) is a straight line joining a point on the other diagonal line E (15) of an XY grid groove with a point shifted by a groove pitch of preferably 10%, more preferably 15%, in a direction perpendicular to the diagonal line (15).

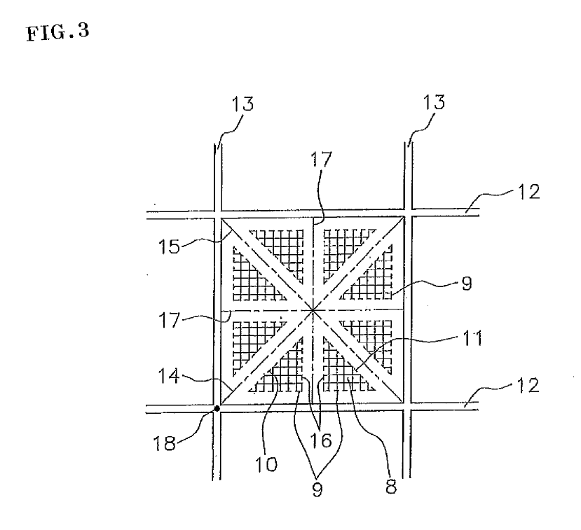

FIG. 3 is a schematic view showing a preferable range of the offset region Z in the present invention.

As shown in FIG. 3, the offset region Z (8) is a region enclosed by three imaginary straight lines A (9), B (10) or C (11), and F (16), and there are 8 offset regions in one XY grid groove. The imaginary straight line F (16) is a straight line shifted by a groove pitch of 5% (preferably 10%, more preferably 15%) in a direction parallel to the center line G (17) passing through the center of the adjacent two X grooves (12) or the adjacent two Y grooves (13). By offsetting the center point of the circular polishing layer in the above range, the occurrence of polishing unevenness on the surface of a material to be polished can be minimized more effectively.

The groove pitch is not particularly limited, but is usually 5 to 50 mm, preferably 10 to 45 mm, and more preferably 15 to 40 mm.

Also, the groove width is not particularly limited, but is usually 0.8 to 7 mm, preferably 1 to 4 mm, and more preferably 1.2 to 2 mm.

The groove depth is appropriately adjusted according to the thickness of the circular polishing layer, but is usually 0.2 to 1.2 mm, preferably 0.4 to 1 mm, and more preferably 0.5 to 0.8 mm.

The circular polishing layer of the present invention can be produced, for example, by forming an XY grid groove on a polishing sheet that is prepared to a predetermined thickness, and then cutting the polishing sheet into a circular shape with reference to the center point that is offset in the region Z.

The circular polishing pad of the present invention may be made of the circular polishing layer alone, or may be a laminate comprising the circular polishing layer and the other layer (for example, a cushion layer, a support film, an adhesive layer, a pressure-sensitive adhesive layer, etc.)

The cushion layer compensates for characteristics of the circular polishing layer. The cushion layer is required for satisfying both planarity and uniformity which are in a tradeoff relationship in CMP. Planarity refers to flatness of a pattern region upon polishing a material to be polished having fine unevenness generated upon pattern formation, and uniformity refers to the uniformity of the whole of a material to be polished. Planarity is improved by the characteristics of the circular polishing layer, while uniformity is improved by the characteristics of the cushion layer. The cushion layer used in the circular polishing pad of the present invention is preferably softer than the circular polishing layer.

The material forming the cushion layer is not particularly limited, and examples of such material include a nonwoven fabric such as a polyester nonwoven fabric, a nylon nonwoven fabric or an acrylic nonwoven fabric, a nonwoven fabric impregnated with resin such as a polyester nonwoven fabric impregnated with polyurethane, polymer resin foam such as polyurethane foam and polyethylene foam, rubber resin such as butadiene rubber and isoprene rubber, and photosensitive resin.

Means for adhering the circular polishing layer to the cushion layer include: for example, a method in which a double-sided tape is sandwiched between the circular polishing layer and the cushion layer, followed by pressing.

The double-sided tape is of a common construction in which adhesive layers are provided on both surfaces of a substrate such as a nonwoven fabric or a film. It is preferable to use a film as a substrate with consideration given to prevention of permeation of a slurry into a cushion sheet. A composition of an adhesive layer is, for example, of a rubber-based adhesive, an acrylic-based adhesive or the like. An acrylic-based adhesive is preferable because of less of a content of metal ions, to which consideration is given. Since a circular polishing layer and a cushion layer is sometimes different in composition from each other, different compositions are adopted in respective adhesive layers of double-sided tape to thereby also enable adhesive forces of the respective adhesive layers to be adjusted to proper values.

A circular polishing pad of the invention may be provided with a double-sided tape on the surface of the pad adhered to a platen. As the double-sided tape, a tape of a common construction can be used in which adhesive layers are, as described above, provided on both surfaces of a substrate. As the substrate, for example, a nonwoven fabric or a film is used. Preferably used is a film as a substrate since separation from the platen is necessary after the use of a circular polishing pad. As a composition of an adhesive layer, for example, a rubber-based adhesive or an acrylic-based adhesive is exemplified. Preferable is an acrylic-based adhesive because of less of metal ions in content to which consideration is given.

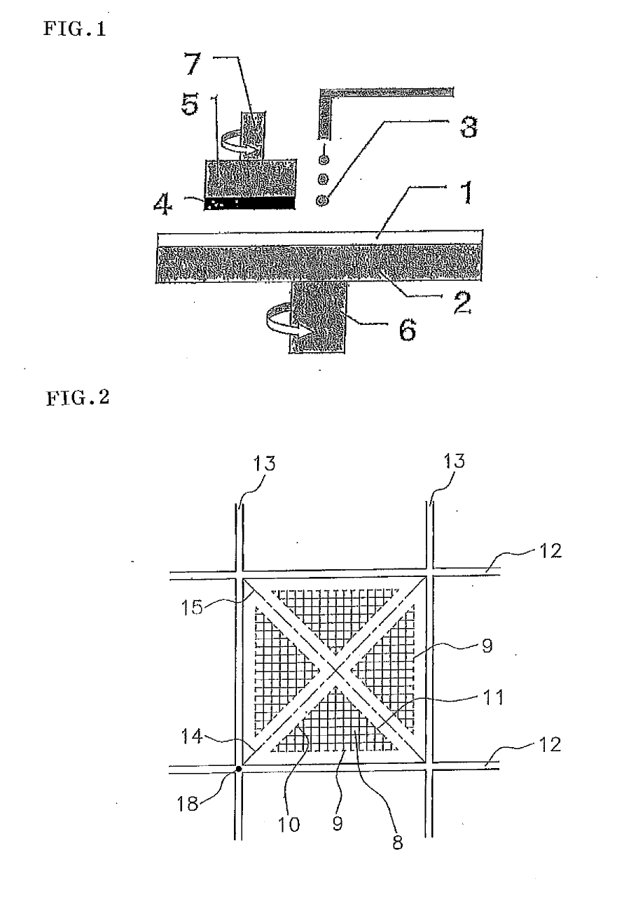

A semiconductor device is fabricated after operation in a step of polishing a surface of a semiconductor wafer with a circular polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a circular polishing pad (a circular polishing layer) 1, a polishing head 5 holding a semiconductor wafer 4, a backing material for applying a uniform pressure against the wafer and a supply mechanism of a polishing agent 3. The circular polishing pad 1 is mounted on the polishing platen 2 by adhering the pad to the platen with a double-sided tape. The polishing platen 2 and the polishing head 5 are disposed so that the circular polishing pad 1 and the semiconductor wafer 4 supported or held by them oppositely face each other and provided with respective rotary shafts 6 and 7. A pressure mechanism for pressing the semiconductor wafer 4 to the circular polishing pad 1 is installed on the polishing head 5 side. During polishing, the semiconductor wafer 4 is polished by being pressed against the circular polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

### Example 1

To a polymerization vessel were added 100 parts by weight of a polyether-based prepolymer (Adiprene L-325, manufactured by Uniroyal Chemical Corporation, with an NCO concentration of 2.22 meq/g) and 3 parts by weight of a silicone-based surfactant (SH192, manufactured by Dow Corning Toray Silicone Co., Ltd.), and then mixed. The mixture was adjusted to 80° C. in the vessel and was defoamed under reduced pressure. Subsequently, the reaction system was vigorously stirred for about 4 minutes with a stirring blade at a rotational speed of 900 rpm so that air bubbles were incorporated into the reaction system. To the reaction system, 26 parts by weight of 4,4′-methylenebis(o-chloroaniline) (IHARACUAMINE MT, manufactured by IHARA CHEMICAL INDUSTRY CO., LTD.) melted at 120° C. in advance was added. Thereafter, the reaction system was continuously stirred for about 1 minute and the reaction solution was poured into a pan type open mold. When the reaction solution lost fluidity, it was put into an oven and postcured at 110° C. for 6 hours to obtain a polyurethane resin foam block.

While heated at 80° C., the polyurethane resin foam block was sliced using a slicer (VGW-125, manufactured by AMITEC Corporation), so that a polishing sheet made of a polyurethane resin foam (average cell diameter: 50 μm, specific gravity: 0.86, hardness: 52 degrees) was obtained. Subsequently, the surface of the polishing sheet was buffed using a buffing machine (manufactured by AMITEC Corporation) until its thickness reached 1.27 mm, thereby to obtain a sheet with regulated thickness accuracy. Then, XY grid grooves with a width of 2 mm, a pitch of 25 mm, and a depth of 0.6 mm were formed on the surface of the polishing sheet using a grooving machine (manufactured by Techno Corporation Co., Ltd.).

After that, with reference to the intersection point of the X and Y grooves (coordinates (0 mm, 0 mm)), the position at coordinates (2.5 mm, 10 mm) was determined as an offset center point. Then, the polishing sheet was cut into a circular shape with a diameter of 61 cm with reference to the offset center point, thereby to prepare a circular polishing layer. Using a laminator, a double-sided adhesive tape (Double Tack Tape, manufactured by SEKISUI CHEMICAL CO., LTD.) was stuck onto the surface opposite to the grooved surface of the circular polishing layer. Further, the surface of a corona-treated cushion layer (Toraypef (0.8 mm-thick polyethylene foam), manufactured by TORAY INDUSTRIES, INC.) was buffed. The buffed cushion layer was stuck onto the double-sided adhesive tape using a laminator. Another double-sided adhesive tape was also stuck onto the other side of the cushion sheet using a laminator so that a circular polishing pad was prepared.

### Examples 2 to 5 and Comparative Examples 1 to 4

A circular polishing pad was prepared in the same manner as in Example 1, except that the groove pitch and the coordinates of the center point of the circular polishing layer were changed to the values described in Table 1.

### [Evaluation Method]

### (Evaluation of Polishing Unevenness)

Using a polishing apparatus SPP600S (manufactured by Okamoto Machine Tool Works, Ltd.), an 8-inch silicon wafer having a 10000 angstrom-thick thermally oxidized film was polished with the prepared circular polishing pad for 2 minutes. Then, polishing unevenness of the polished surface of the wafer was visually observed and evaluated by the following criteria.

◯: No occurrence of concentric stripe unevenness
x: Occurrence of concentric stripe unevenness

The polishing conditions were as follows: a slurry (SS-25, manufactured by Cabot) that was diluted two-fold with ultrapure water was added at a flow rate of 150 ml/minute during polishing, wherein the polishing load was 254 g/cm², the polishing platen rotation speed was 90 rpm, and the wafer rotation speed was 91 rpm. Also, before polishing, the surface of the circular polishing pad was dressed using a dresser (M100 type, manufactured by Asahi Diamond Industrial Co., Ltd.) for 20 seconds. The dressing conditions were as follows: the dressing load was 10 g/cm², the polishing platen rotation speed was 30 rpm, and the dresser rotation speed was 15 rpm.

TABLE 1

| | | | | | | Comparative | Comparative | Comparative | Comparative |
|---|---|---|---|---|---|---|---|---|---|
| | Example 1 | Example 2 | Example 3 | Example 4 | Example 5 | example 1 | example 2 | example 3 | example 4 |
| Groove pitch (mm) | 25 | 25 | 25 | 15 | 40 | 25 | 25 | 25 | 40 |
| Coordinates of | (2.5, 10) | (5, 7.5) | (5, 12.5) | (2, 5) | (5, 15) | (0, 0) | (0, 12.5) | (12.5, 12.5) | (0, 0) |
| center point | | | | | | | | | |
| (mm, mm) | | | | | | | | | |
| Polishing | ◯ | ◯ | ◯ | ◯ | ◯ | X | X | X | X |
| unevenness | | | | | | | | | |

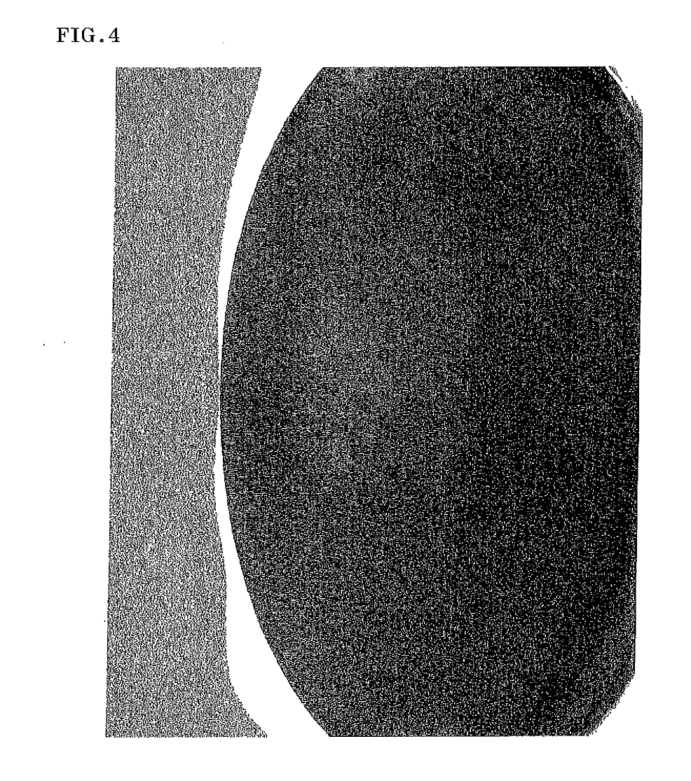

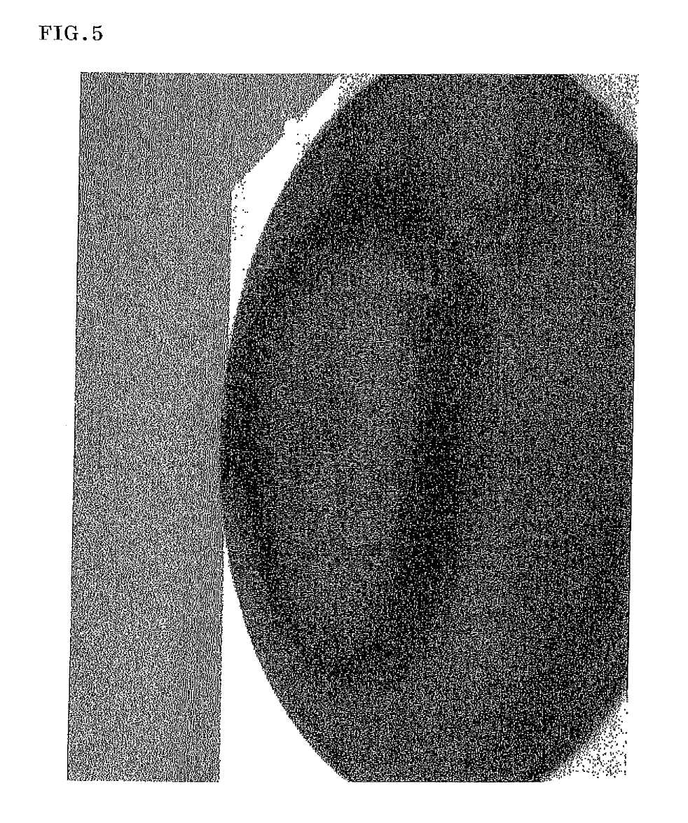

FIG. 4 is a photograph showing the state of the polished surface after polishing a wafer using the circular polishing pad of Example 1. It is understood that the wafer was polished uniformly without causing the occurrence of concentric polishing unevenness on the polished surface. FIG. 5 is a photograph showing the state of the polished surface after polishing a wafer using the circular polishing pad of Comparative Example 1. It is understood that the wafer has concentric polishing unevenness in the central portion of the polished surface.

### INDUSTRIAL APPLICABILITY

A circular polishing pad of the invention is capable of performing planarization materials requiring a high surface planarity such as optical materials including a lens and a reflective mirror, a silicon wafer, a glass substrate or an aluminum substrate for a hard disk and a product of general metal polishing with stability and a high polishing efficiency. A circular polishing pad of the invention is preferably employed, especially, in a planarization step of a silicon wafer or a device on which an oxide layer or a metal layer has been formed prior to further stacking an oxide layer or a metal layer thereon.

### DESCRIPTION OF REFERENCE SIGNS

In the drawings, reference numeral 1 represents a polishing pad (a circular polishing pad), 2 a polishing platen, 3 a polishing agent (slurry), 4 a material to be polished (semiconductor wafer), 5 a supporting stand (polishing head), 6 and 7 each a rotating shaft, 8 an offset region Z, 9 an imaginary straight line A, 10 an imaginary straight line B, 11 an imaginary straight line C, 12 a X groove, 13 a Y groove, 14 a diagonal line D, 15 a diagonal line E, 16 an imaginary straight line F, 17 a center line G, 18 an intersection point of X and Y grooves.

1. A circular polishing pad including a circular polishing layer having XY grid grooves on a polishing surface, wherein the center point of the circular polishing layer is offset in a region Z (including imaginary straight lines) enclosed by the following three imaginary straight lines A, B and C:
imaginary straight line A: a straight line joining a point on an X groove or a Y groove with a point shifted by a groove pitch of 5% in a direction perpendicular to the X groove or Y groove,
imaginary straight line B: a straight line joining a point on one diagonal line D of an XY grid groove with a point shifted by a groove pitch of 5% in a direction perpendicular to the diagonal line D, and
imaginary straight line C: a straight line joining a point on the other diagonal line E of the XY grid groove with a point shifted by a groove pitch of 5% in a direction perpendicular to the diagonal line E.

2. A method for producing the circular polishing pad according to claim 1, comprising the steps of:
forming an XY grid groove in a polishing sheet, and
preparing a circular polishing layer by cutting the polishing sheet into a circular shape with reference to the center point that is offset in the region Z.

3. A method for manufacturing a semiconductor device, comprising the step of polishing the surface of a semiconductor wafer by using the circular polishing pad according to claim 1.
